(19) United States
(12) Patent Application Publication
(10) Pub. No.: US 2007/0211037 A1
(43) Pub. Date: Sep. 13, 2007

(54) Photoelectric sensing array apparatus

(76) Inventor: Brian Y. Sun, Garland, TX (US)

Correspondence Address: SCOTT T. GRIGGS, 901 MAIN STREET, SUITE 6300, DALLAS, TX, 75202, US

(21) Appl. No.: 11/372,458

(22) Filed: Mar. 9, 2006

(51) Int. Cl. H01L 31/00; G06F 3/041

(52) U.S. Cl. 345/173

(57) ABSTRACT

A photoelectric sensing array assembly is disclosed for use in combination with an optical touch screen that is externally adaptable to a video monitor for serving as an input device to an electronic device connected to the video monitor. More particularly, the photoelectric sensing array utilizes interconnectable segment components of a variety of standardized sizes to permit the construction of optical touch screens of any dimension. In one implementation, first and second pairs of rails are mounted in a frame-like configuration in photoelectric communication for detecting the presence of an opaque object disposed therebetween. Each one of the rails includes a plurality of interconnected segment components having an arrangement of photoelectric elements disposed thereon.

### TECHNICAL FIELD OF THE INVENTION

This invention relates, in general, to optical touch screens and, in particular, to a photoelectric sensing array apparatus that senses the position of an opaque object located within a single or multi-dimensional array of photoelectric elements.

### BACKGROUND OF THE INVENTION

Existing optical touch screens that incorporate photoelectric technology are specifically designed and built to predetermined specifications that are equal to or larger than the viewing area of a video monitor. Therefore, optical touch screen manufacturers must design and manufacture many different sized optical touch screens in order to match the variety of video monitors available on the market. This ad hoc effort has inevitably increased the cost of manufacturing due to the different sizes of required tooling and fixtures and slowed down the response to marketplace needs. Accordingly, the existing optical touch screen market is characterized by high-cost, low-volume production and a need exists for a low-cost, high-volume production solution.

### SUMMARY OF THE INVENTION

A photoelectric sensing array assembly is disclosed for use in combination with an optical touch screen that is externally adaptable to a video monitor for serving as an input device to an electronic device connected to the video monitor. The photoelectric sensing array presented herein offers a low-cost, high-volume production solution. More particularly, the photoelectric sensing array utilizes interconnectable segment components of a variety of standardized sizes to permit the construction of optical touch screens of any dimension.

In one implementation, a first pair of rails are mounted in photoelectric communication with one another for detecting the presence of an opaque object disposed therebetween. A second pair of rails are mounted in photoelectric communication and disposed substantially orthogonally to the first pair of rails in a frame-like configuration to define a viewing area. Each one of the rails includes a plurality of interconnected segment components having an arrangement of photoelectric elements disposed thereon.

### BRIEF DESCRIPTION OF THE DRAWINGS

For a more complete understanding of the features and advantages of the present invention, reference is now made to the detailed description of the invention along with the accompanying figures in which corresponding numerals in the different figures refer to corresponding parts and in which:

FIG. 1 is a front perspective view of one embodiment of a photoelectric sensing array assembly incorporated into an optical touch screen that is externally adaptable to a video monitor for serving as an input device to an electronic device connected to the video monitor;

FIG. 2 is a block circuit diagram of one embodiment of the electronics associated with the photoelectric sensing array assembly;

FIG. 3 is a front elevation view of the video monitor utilizing the photoelectric sensing array assembly;

FIG. 4 is a cross sectional view of FIG. 3 along section line 4-4′ as shown;

FIG. 5 is a front elevation view of the photoelectric sensing array assembly;

FIG. 6 is a schematic view depicting one embodiment of the construction of a portion of the photoelectric sensing array assembly;

FIG. 7 is a side elevation view depicting a portion of the construction presented in FIG. 6 in further detail;

FIG. 8 is a schematic view depicting a portion of the construction presented in FIG. 6 in further detail; and

FIG. 9 is a schematic view depicting one embodiment of the construction of a different portion than presented in FIG. 7 of the photoelectric sensing array assembly.

### DETAILED DESCRIPTION OF THE INVENTION

While the making and using of various embodiments of the present invention are discussed in detail below, it should be appreciated that the present invention provides many applicable inventive concepts which can be embodied in a wide variety of specific contexts. The specific embodiments discussed herein are merely illustrative of specific ways to make and use the invention, and do not delimit the scope of the present invention.

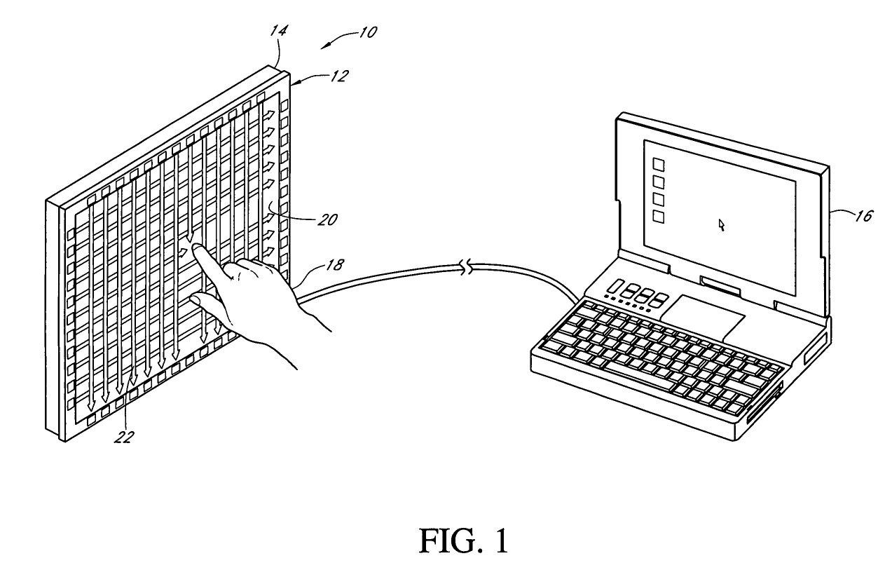

FIG. 1 depicts one embodiment of a photoelectric sensing array assembly 10 incorporated into an optical touch screen 12 that is externally adaptable to a video monitor, which is illustrated as a television 14, for serving as an input device to an electronic device, which is depicted as a computer 16, connected to the television 14. The optical touch screen 12 is an interactive computer input device which allows an operator to input a command to the computer by placing an opaque object, such as a finger of hand 18 of the operator, within the viewing area 20 of the television 14 to select a command graphically displayed on the television 14 by the computer 16.

More specifically, as will be explained in further detail hereinbelow, a first pair of rails are mounted in photoelectric communication with one another and, similarly, a second pair of rails are mounted in photoelectric communication. The first and second pairs of rails are disposed substantially orthogonally to each other around the viewing area 20. Each one of the rails includes a plurality of interconnected segment components having an arrangement of photoelectric elements disposed thereon. The interconnected segment components are available in a variety of lengths in order to construct an optical touch screens for any video monitor. The photoelectric elements generate an invisible infrared (IR) beam grid 22 which is interrupted or blocked by the finger. Electronic components associated with the photoelectric elements determine the location of the interruption.

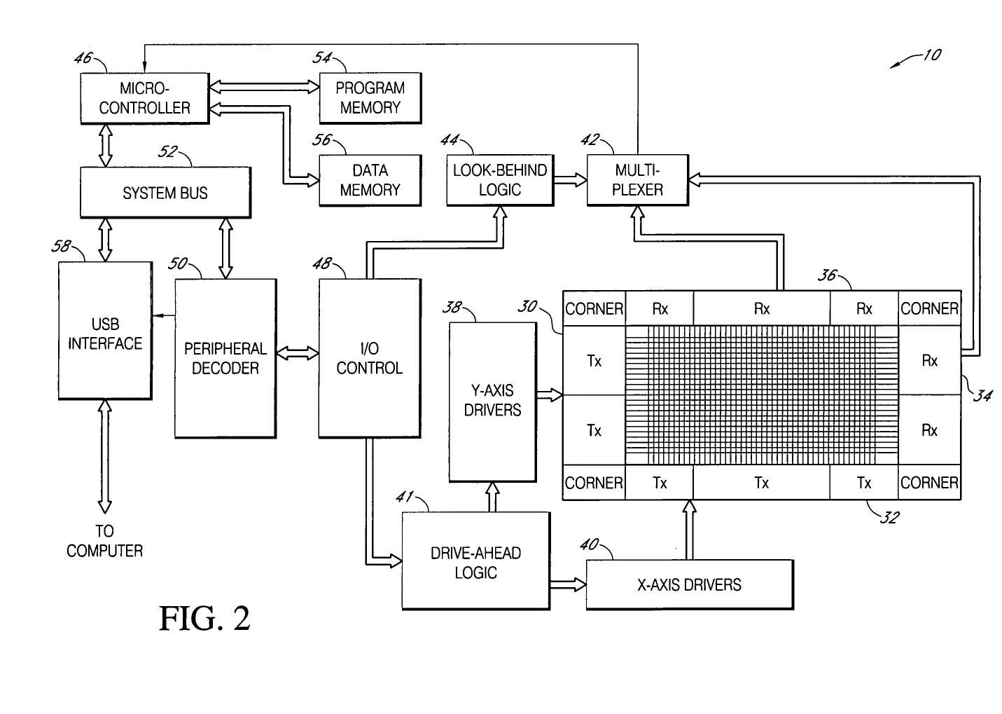

FIG. 2 depicts one embodiment of the electronics associated with the photoelectric sensing array assembly 10. The photoelectric sensing array assembly 10 includes arrangements 30, 32 of light emitting diode transmitters disposed along the left-hand side and bottom of the photoelectric sensing array assembly 10 and corresponding arrangements 34, 36 of light sensing receivers disposed at the right-hand side and the top of the photoelectric sensing array assembly 10. The arrangements 30, 32 are activated by y-axis and x-axis drivers 38 and 40, respectively, which are in turn controlled by drive-ahead logic 41. The arrangements 34, 36 are connected to a multiplexer 42 which is controlled by look-behind logic 44.

The drive-ahead logic 41 and the look-behind logic 44 communicate with a microcontroller 46 by way of an I/O control 48, a peripheral decoder 50, and a system bus 52. The multiplexer 42 additionally has a feedback to the microcontroller 46 which includes a program memory 54 and a data memory 56, which for purposes of illustration are separately shown. The output of the optical touch screen 12 is communicated by the microcontroller 46 as an input to the computer 16 by way of a universal serial bus (USB) interface 58. It should be appreciated that although a specific architecture is presented in FIG. 2, the electronics and associated operation of the photoelectric sensing array assembly 10 may have a different architecture.

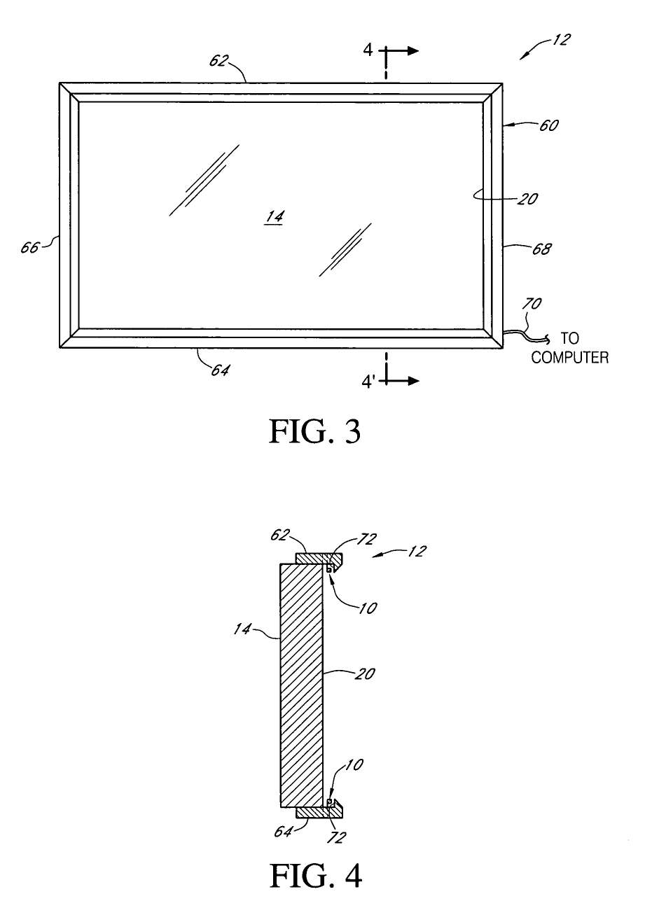

FIGS. 3 and 4 depict the television 14 utilizing the photoelectric sensing array assembly 10. The optical touch screen 12 includes a bezel or frame 60 having top and bottom portions 62, 64 and side portions 66, 68. The side portion 68 of the frame includes a cable 70 that connects the optical touch screen 12 to the computer 16. The frame 60 is fitted and secured to the television 14 to define the viewing area 20. As best seen in FIG. 4, the photoelectric sensing array assembly 10 is suitably mounted in an interior recess 72 formed within the top portion 62, the bottom portion 64, and the side portions 66, 68 of the frame 60. Hence, the photoelectric sensing array assembly 10 and optical touch screen 12 presented herein is externally adapted to any video monitor for serving as an input device to a computer by connecting the optical touch screen 12 to a computer via a USB interface or other type of port connection.

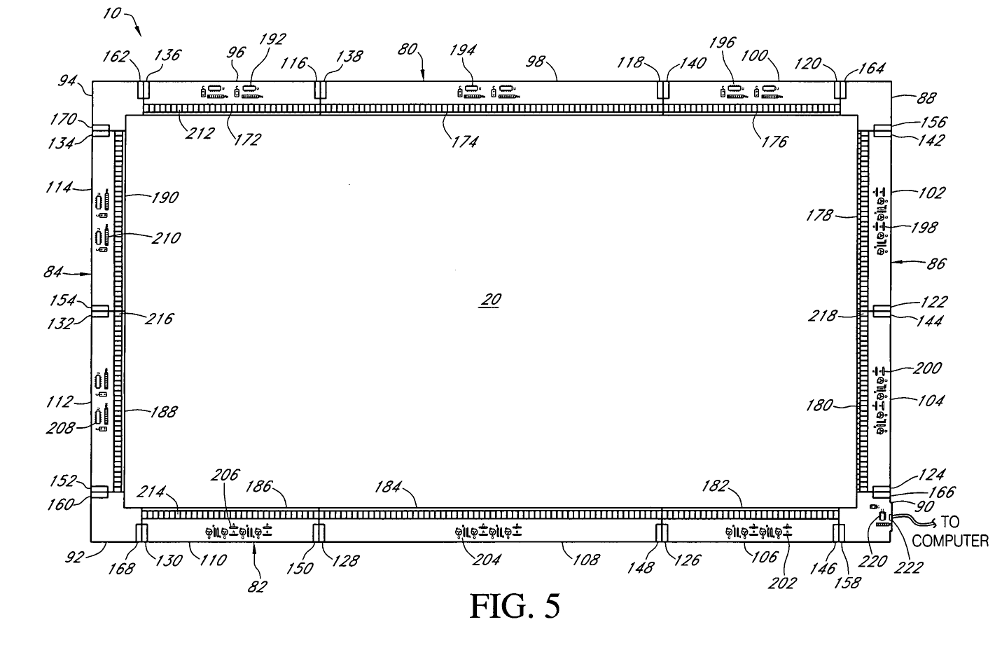

FIG. 5 depicts the photoelectric sensing array assembly 10. Rails 80, 82 are mounted in photoelectric communication with one another to define a single dimensional array for detecting the presence of an opaque object disposed therebetween. Similarly, rails 84, 86 are disposed substantially orthogonally to the rails 80, 82 to define the viewing area 20. The rails 84, 86 are also mounted in photoelectric communication with one another to define a single dimensional array for detecting the presence of the opaque object disposed therebetween. Together, the rails 80, 82, 84, 86 define a multi-dimensional array having both an x-axis and a y-axis. Four corner components 88, 90, 92, 94 connect rails 80, 82, 84, 86. More specifically, the corner component 88 connects the rails 80, 86; the corner component 90 connects the rails 86, 82; the corner component 92 connects the rails 82, 84; and the corner component 94 connects the rails 84, 80.

Each one of the rails 80, 82, 84, 86 includes a plurality of interconnected segment components. The rail 80 includes interconnected segment components 96, 98, 100; the rail 82 includes interconnected segment components 106, 108, 110; the rail 84 includes interconnected segment components 112, 114; and the rail 86 includes interconnected segment components 102, 104.

Male connectors, which are labeled 116-134, as well as female connectors, which are labeled 136-154, are associated the rails 96-114, respectively. Similarly, the corner components 88-94 have male connectors 156-162 and female connectors 164-170, respectively. In the illustrated embodiment, as each segment component 96-114 and each corner component 88-94 includes one male and one female connector, the segment components 96-114 and corner components 88-94 are interconnected to form the photoelectric sensing array assembly 10 and the optical touch screen 12 by connecting the male and female connections. By way of example, to form the rail 80, the male connector 162 of the corner component 94 is inserted into the female connector 136 of the segment component 96. The male connector 116 of the segment connector 96, in turn, is connected to the female connector 138 of the segment component 98. The segment components 98, 100 are connected by the male connector 118 and the female connector 140. Lastly, the male connector 120 of the segment component 100 is connected to the female connector 164 of the corner component 88. The other portions of the photoelectric sensing array assembly 10 are similarly interconnected.

Photoelectric elements, which are labeled 172-190, are associated with the rails 96-114, respectively. Similarly, electronic components, which are labeled 192-210, are associated with the rails 96-114, respectively, too. The photoelectric elements 172-190 on opposing rails are complimentary. For example, the photoelectric elements 172 on the segment component 96 compliment the photoelectric elements 186 on the segment component 110. By way of the further illustration, if photoelectric element 212 is a light sensing receiver, then the opposing photoelectric element 214 is a light emitting diode transmitter. Similarly, if photoelectric element 216 of the segment component 112 is a light emitting diode transmitter, then the opposing photoelectric element 218 of the segment component 104 is a light sensing receiver. As illustrated, the rails 106-114 include light emitting diode transmitters and the corresponding rails 96-104 include light sensing receivers. It should be appreciated, however, that any segment component or rail may include light emitting diode transmitters, light sensing receivers, or both light emitting diode transmitters and light sensing receivers.

The electronic components 192-210 drive the photoelectric elements 172-190 by pulsing the light emitting diode transmitters of photoelectric elements 182-190 and electronically sensing the response at the corresponding light sensing receivers of photoelectric elements 172-180. A multitude of invisible IR beams is produced by this arrangement, whereby light sensing receivers are blocked at the position where the opaque object is located. The center point of the opaque object is determined by electrically sensing current flow in the light sensing receivers 172-180 and cross-referencing the light sensing receivers 172-180 blocked on the x-axis, which as illustrated is parallel with rails 80, 82, and the y-axis, which is parallel with rails 84, 86.

In one embodiment, the corner components 88-94 provide mechanical and electrical connections between the rails 80-86 and the corner components 88 and 92-94 include minimal electronic components. In this embodiment, the electronic components are distributed between the rails 80-86 and the corner component 90, which includes electronic components 220 and an interface 222 for connecting the optical touch screen 12 to the computer 16. For example, a portion of the electronic architecture presented in FIG. 2 may be disposed on the corner component 90 and embodied in electronic components 220. It should be appreciated, however, that other distribution arrangements are within the teachings of the present invention. For instance, a portion of the electronic architecture may be disposed within an external controller that is disposed between the optical touch screen 12 and the computer 16.

In one implementation, the segment components 96-114 are available in several different lengths. In particular, although only two lengths of segment components are depicted in FIG. 5, the segment components 96-114 may be manufactured and made available in any number of lengths. By analyzing the most common factors among the commercially available video monitors, the optimal lengths for the segment components may be determined in order to permit the most economical way of producing optical touch screens of any dimension.

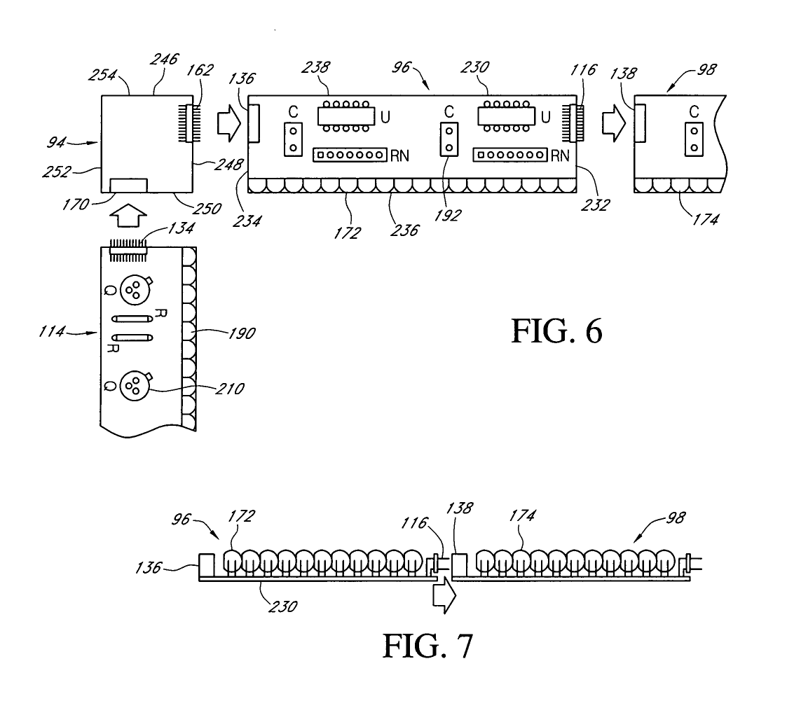

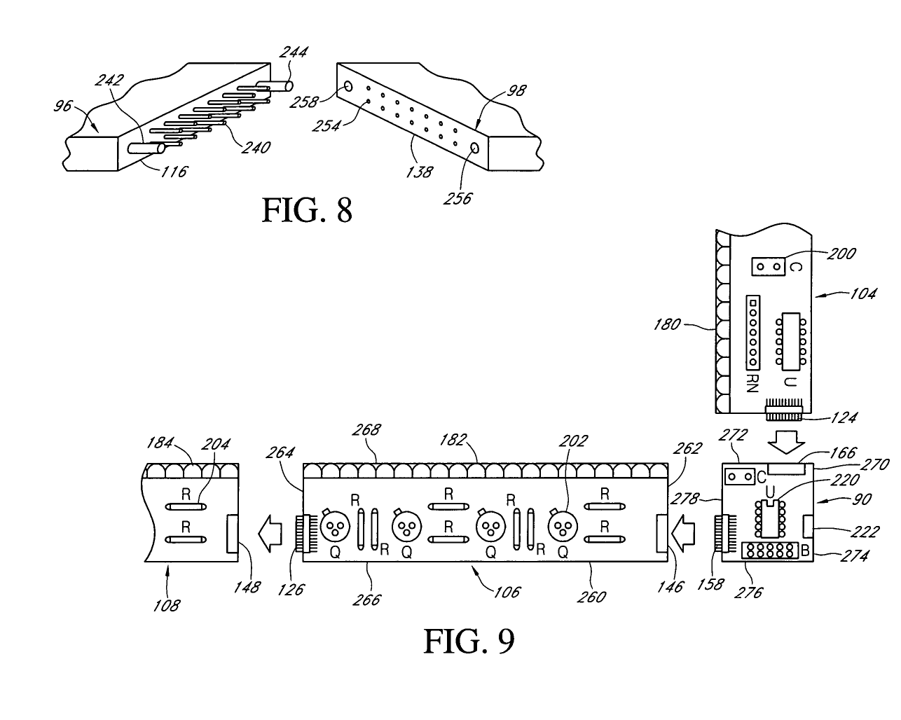

FIG. 6 depicts one embodiment of the construction of a portion of the photoelectric sensing array assembly 10. The segment component 96 includes a printed circuit board 230 having ends 232, 234 and edges 236, 238. The male connector 116 is disposed at end 232 and the female connector 136 is disposed at the end 234. In one embodiment, as best seen in FIGS. 7 and 8, the male connector 116 includes numerous terminal pins or prongs 240 as well as two threaded guide pins 242, 244. Referring again to FIG. 6, the female connector 136 includes receptacle apertures for accepting the pins and guide holes for receiving the threaded guide pins.

As previously discussed, an arrangement of photoelectric elements 172 are disposed on the printed circuit board 230 proximate to the edge 236 between the ends 232, 234. Electronic components 192 are associated with the printed circuit board 230 for driving the photoelectric elements 172 which are depicted as light sensing receivers. Additionally, a plurality of conductive pathways are associated with the printed circuit board 230. The plurality of conductive pathways interconnect the male connector 116, the female connector 136, the arrangement of photoelectric elements 172, and the electronic components 192.

The corner component 94 includes a printed circuit board 246 having edges 248-254. The male connector 162, which includes numerous terminal pins and two threaded guide pins, is disposed at edge 248 and the female connector 170, which includes a receptacle aperture, is disposed at edge 250. Conductive pathways electrically couple the male and female connectors 156, 170. Partially depicted in FIG. 6 are the segment component 114, which includes the male connector 134 having numerous terminal pins and two threaded guide pins, and the segment component 98, which includes the female connector 138 having, as best seen in FIGS. 7 and 8, receptacle apertures 254 for accepting the pins 240 and guide holes 256, 258 for receiving the threaded guide pins 242, 244, respectively.

Returning to FIG. 6, the segment components 96, 98, 114 and the corner component 94 are connected together by aligning the threaded guide pins of the male connectors with the guide holes of the female connectors belonging to a different component as indicated by the arrows. As best seen in FIGS. 7 and 8, with respect to the component segment 96 and the component segment 98, the guide pins 242, 244 are inserted in and fastened to the guide holes 256, 258 such that the pins 240 are received by the apertures 254. Please note that in FIG. 7 for purposes of illustration and explanation the photoelectric elements closest to the male and female connectors are not depicted. Butterfly nuts may be utilized to secure the connections between the guide pins 242, 244 and the guide holes 256, 258. The connection is sufficiently tight to provide a good electrical connection as well as a good mechanical connection. Additionally, in some embodiments, it should be appreciated that no tools are required to secure the connections. Although a plug and socket connection arrangement for the segment and corner components is described herein, it should be appreciated that other types of connection arrangements are within the teachings of the present invention. For example, hermaphroditic connectors may be utilized as well as connection arrangements that utilize gender changing connection components.

FIG. 9 depicts one embodiment of the construction of a different portion than presented in FIG. 7 of the photoelectric sensing array assembly. The segment component 106 includes a printed circuit board 260 having ends 262, 264 and edges 266, 268. The male connector 126 is disposed at end 264 and a female connector 146 is disposed at the end 262. The arrangement of photoelectric elements 182, which are depicted as light emitting diode transmitters, electronic components 202, and a plurality of conductive pathways are disposed on the printed circuit board 260.

The corner component 90 includes a printed circuit board 270 having edges 272-278 and the male connector 158 and the female connector 166 are disposed thereon. Conductive pathways electrically couple the male and female connectors 160, 166 as well as the electronic components 220 which carry out a portion of the functions described in FIG. 2. The USB interface 222 is also disposed on the corner component 90. Partially depicted in FIG. 9 are the segment component 104 which includes a male connector 124 and the segment component 108 which includes a female connector 148. The component segments 104, 106, 108 and corner segment 90 are interconnected in a manner similar to that described in FIGS. 6-8. It should be appreciated that although construction of the photoelectric sensing array assembly and the optical touch screen is depicted in FIGS. 6-9, the photoelectric sensing array assembly can be disassembled, altered, and resized by disconnecting the interconnected segment components.

The segment components described herein may be mass produced relatively inexpensively and the modularized segment components may be interconnected to build a photoelectric sensing array assembly and optical touch screen for any size of video monitor. Accordingly, the segment components and related photoelectric sensing array assembly commoditize optical touch screen construction, thereby decreasing manufacturing costs and increasing production efficiency.

While this invention has been described with reference to illustrative embodiments, this description is not intended to be construed in a limiting sense. Various modifications and combinations of the illustrative embodiments as well as other embodiments of the invention, will be apparent to persons skilled in the art upon reference to the description. It is, therefore, intended that the appended claims encompass any such modifications or embodiments.

What is claimed is:

1. An apparatus for use in combination with an optical touch screen that is externally adaptable to a video monitor for serving as an input device to an electronic device connected to the video monitor, the apparatus comprising:
a printed circuit board having a first end and a second end;
a male connector disposed at the first end;
a female connector disposed at the second end;
an arrangement of photoelectric elements disposed on the printed circuit board proximate an edge between the first and second ends;
electronic components associated with the printed circuit board, the electronic components for driving the photoelectric elements; and
a plurality of conductive pathways associated with the printed circuit board, the plurality of conductive pathways interconnecting the male connector, the female connector, the arrangement of photoelectric elements, and the electronic components.

2. The apparatus as recited in claim 1, wherein the arrangement of photoelectric elements comprises light emitting diode transmitters.

3. The apparatus as recited in claim 1, wherein the arrangement of photoelectric elements comprises light sensing receivers.

4. The apparatus as recited in claim 1, wherein the arrangement of photoelectric elements comprises light emitting diode transmitters and light sensing receivers.

5. A photoelectric sensing rail assembly, comprising:
a first segment component having a male connector disposed at a first end and a female connector disposed at a second end, the first segment component including an arrangement of photoelectric elements disposed between the first and second ends; and
a second segment component having a male connector disposed at a first end and a female connector disposed at a second end, the second segment component including an arrangement of photoelectric elements disposed between the first and second ends,
wherein the male connector of the first segment component is coupled to the female connector of the second segment component to provide for electronic communication therethrough.

6. The assembly as recited in claim 5, wherein the arrangement of photoelectric elements on the first segment component comprises light emitting diode transmitters.

7. The assembly as recited in claim 5, wherein the arrangement of photoelectric elements on the first segment component comprises light sensing receivers.

8. The assembly as recited in claim 5, wherein the arrangement of photoelectric elements on the first segment component comprises light emitting diode transmitters and light sensing receivers.

9. A photoelectric sensing array assembly, comprising:
a first plurality of interconnected segment components, each of the first plurality of interconnected segment components including an arrangement of photoelectric elements; and
a second plurality of interconnected segment components disposed in photoelectric communication with the first plurality of interconnected segment components, each of the second plurality of interconnected segment components including a complimentary arrangement of photoelectric elements,
wherein the complimentary arrangement opposes the arrangement to detect the presence of an opaque object disposed therebetween.

10. The assembly as recited in claim 9, wherein the arrangement of photoelectric elements on the first plurality of interconnected segment components comprises light sensing receivers.

11. The assembly as recited in claim 9, wherein the arrangement of photoelectric elements on the first plurality of interconnected segment components comprises light emitting diode transmitters.

12. The assembly as recited in claim 9, wherein the arrangement of photoelectric elements on the first plurality of interconnected segment components comprises light emitting diode transmitters and light sensing receivers.

13. A photoelectric sensing array assembly, comprising:
a first pair of rails mounted in photoelectric communication with one another for detecting the presence of an opaque object disposed therebetween, each one of the rails including a plurality of interconnected segment components having an arrangement of photoelectric elements disposed thereon; and
a second pair of rails disposed substantially orthogonally to the first pair of rails to define a viewing area, the second pair of rails mounted in photoelectric communication with one another for detecting the presence of the opaque object disposed therebetween, each one of the rails including a plurality of interconnected segment components having an arrangement of photoelectric elements disposed thereon.

14. The assembly as recited in claim 13, wherein the arrangement of photoelectric elements on the first pair of rails comprises light sensing receivers.

15. The assembly as recited in claim 13, wherein the arrangement of photoelectric elements on the first pair of rails comprises light emitting diode transmitters.

16. The assembly as recited in claim 13, wherein the arrangement of photoelectric elements on the first pair of rails comprises light emitting diode transmitters and light sensing receivers.

17. The assembly as recited in claim 13, further comprising four corner components connecting the first pair of rails and the second pair of rails in a frame.

18. A photoelectric sensing rail assembly, comprising:
a first segment component including an arrangement of photoelectric elements disposed along an edge associated with the first segment component;
a second segment component including an arrangement of photoelectric elements disposed along an edge associated with the second segment component; and
means for electrically and mechanically coupling the first segment to the second segment.

19. The assembly as recited in claim 18, wherein the arrangement of photoelectric elements on the first segment comprises light sensing receivers.

20. The assembly as recited in claim 18, wherein the arrangement of photoelectric elements on the first segment comprises light emitting diode transmitters.

21. The assembly as recited in claim 18, wherein the arrangement of photoelectric elements on the first segment comprises light emitting diode transmitters and light sensing receivers.
